(19) United States
(12) Patent Application Publication
(10) Pub. No.: US 2020/0411507 A1
(43) Pub. Date: Dec. 31, 2020

(54) SEMICONDUCTOR DEVICES

(71) Applicant: Samsung Electronics Co., Ltd., Suwon-si (KR)

(72) Inventors: Hyojoon An, Suwon-si (KR); Han-Kyung Kim, Seongnam-si (KR); Sang-Min Noh, Hwaseong-si (KR); Jaewoo Yang, Ulsan (KR); Hyungwoo Yu, Taean-gun (KR); Gunwoo Lee, Goyang-si (KR); Gwangmin Lee, Ulsan (KR); Seungkwon Lee, Suwon-si (KR)

(73) Assignee: Samsung Electronics Co., Ltd., Suwon-si (KR)

(21) Appl. No.: 16/783,333

(22) Filed: Feb. 6, 2020

(30) Foreign Application Priority Data
Jun. 27, 2019 (KR) 10-2019-0077298

(51) Int. Cl. H01L 27/06; H01L 49/02; H01L 23/528; H01L 23/522

(52) U.S. Cl. CPC H01L 27/0629; H01L 28/60; H01L 23/53257; H01L 23/5226; H01L 23/528

(57) ABSTRACT

A semiconductor device includes a substrate that includes a first region and a second region; a switching transistor on the first region of the substrate, an interlayer dielectric layer that covers the switching transistor and is on the second region of the substrate, a cell contact that penetrates the interlayer dielectric layer on the first region of the substrate and is in contact with the switching transistor, and a first dummy contact, a second dummy contact, and a third dummy contact that penetrate the interlayer dielectric layer on the second region of the substrate in a vertical direction and adjacent to each other in a first horizontal direction. The first and second dummy contacts constitute opposing electrodes of a first decoupling capacitor. The second and third dummy contacts constitute opposing electrodes of a second decoupling capacitor. The first to third dummy contacts are electrically isolated from the substrate.

### CROSS-REFERENCE TO RELATED APPLICATION

This U.S. non-provisional application claims priority under 35 U.S.C § 119 to Korean Patent Application No. 10-2019-0077298 filed on Jun. 27, 2019 in the Korean Intellectual Property Office, the entire contents of which are hereby incorporated by reference.

### BACKGROUND

The present inventive concepts relate to semiconductor devices, and more particularly, to semiconductor devices including one or more decoupling capacitors.

Many electronic devices include one or more capacitors for various purposes. As an example, capacitors are included as memory elements in semiconductor memory devices such as dynamic random access memories (DRAMs). As another example, because capacitors are used to store electric energy in energy storage devices, a capacitor may be included in a decoupling circuit of a semiconductor device to reduce the effect of noise, produced in one portion of the semiconductor device, on other portions of the semiconductor device. A semiconductor device is may include a plurality of decoupling circuits in order to have improved noise characteristics.

### SUMMARY

Some example embodiments of the present inventive concepts provide a semiconductor device including a decoupling capacitor.

The present inventive concepts are not limited to the mentioned above, and other inventive concepts which have not been mentioned above will be clearly understood to those skilled in the art from the following description.

According to some example embodiments of the present inventive concepts, a semiconductor device may include a substrate that includes a first region and a second region, a switching transistor on the first region of the substrate, an interlayer dielectric layer that covers the switching transistor and is on the second region of the substrate, a cell contact that penetrates the interlayer dielectric layer on the first region of the substrate and is in contact with the switching transistor; and a first dummy contact, a second dummy contact, and a third dummy contact that penetrate the interlayer dielectric layer on the second region of the substrate in a vertical direction that is perpendicular to a top surface of the substrate. The first dummy contact, the second dummy contact, and the third dummy contact may be adjacent to each other in a first horizontal direction that is parallel to the top surface of the substrate. The first dummy contact and the second dummy contact may constitute opposing electrodes of a first decoupling capacitor. The second dummy contact and the third dummy contact may constitute opposing electrodes of a second decoupling capacitor. The first, second, and third dummy contacts may be electrically isolated from the substrate.

According to some example embodiments of the present inventive concepts, a semiconductor device may include a substrate that includes a first region and a second region, a first impurity region, a second impurity region, and a third impurity region that are adjacent to each other in a first direction on the second region of the substrate, an interlayer dielectric layer on the first and second regions of the substrate, a first dummy contact in the interlayer dielectric layer and in contact with the first impurity region, a second dummy contact in the interlayer dielectric layer and in contact with the second impurity region, a third dummy contact in the interlayer dielectric layer and in contact with the third impurity region, a first dummy conductive line on the interlayer dielectric layer and electrically connected, through separate, respective vias, to the first dummy contact and the third dummy contact, and a second dummy conductive line on the interlayer dielectric layer and electrically connected to the second dummy contact.

According to some example embodiments of the present inventive concepts, a semiconductor device may include a substrate that includes a first region and a second region, a switching transistor on the first region of the substrate, the switching transistor including a gate electrode on the substrate and a source/drain region on the first region, the source/drain region on one side of the gate electrode, an interlayer dielectric layer that covers the switching transistor and is on the second region of the substrate, a first dummy contact and a second dummy contact that penetrate the interlayer dielectric layer on the second region of the substrate in a vertical direction that is perpendicular to a top surface of the substrate, the first dummy contact and the second dummy contact being adjacent to each other in a first horizontal direction that is parallel to the top surface of the substrate, and a cell contact that penetrates the interlayer dielectric layer and is in contact with the source/drain region. A top surface of the first dummy contact, a top surface of the second dummy contact, and a top surface of the cell contact may be coplanar with each other. The first dummy contact and the second dummy contact may constitute opposing electrodes of a decoupling capacitor.

### BRIEF DESCRIPTION OF THE DRAWINGS

FIG. 1 illustrates a plan view showing a semiconductor device according to some example embodiments of the present inventive concepts.

FIG. 2 illustrates a cross-sectional view taken along lines I-I′ and II-II′ of FIG. 1, showing a semiconductor device according to some example embodiments of the present inventive concepts.

FIG. 3 illustrates a cross-sectional view taken along line II-II′ of FIG. 1, showing a semiconductor device according to some example embodiments of the present inventive concepts.

FIG. 4 illustrates a cross-sectional view taken along line II-II′ of FIG. 1, showing a semiconductor device according to some example embodiments of the present inventive concepts.

FIG. 5 illustrates a plan view showing a semiconductor device according to some example embodiments of the present inventive concepts.

FIG. 6 illustrates a cross-sectional view taken along line III-III′ of FIG. 5, showing a semiconductor device according to some example embodiments of the present inventive concepts.

FIG. 7 illustrates a cross-sectional view taken along line III-III′ of FIG. 5, showing a semiconductor device according to some example embodiments of the present inventive concepts.

FIG. 8 illustrates a cross-sectional view taken along line III-III′ of FIG. 5, showing a semiconductor device according to some example embodiments of the present inventive concepts.

FIG. 9 illustrates a plan view showing a semiconductor device according to some example embodiments of the present inventive concepts.

FIG. 10 illustrates a cross-sectional view taken along line IV-IV′ of FIG. 9, showing a semiconductor device according to some example embodiments of the present inventive concepts.

FIG. 11 illustrates a plan view showing a semiconductor device according to some example embodiments of the present inventive concepts.

FIG. 12 illustrates a cross-sectional view taken along lines V-V′ and VI-VI′ of FIG. 11, showing a semiconductor device according to some example embodiments of the present inventive concepts.

FIG. 13 illustrates a plan view showing a semiconductor device according to some example embodiments of the present inventive concepts.

FIG. 14 illustrates a cross-sectional view taken along line VII-VII′ of FIG. 13, showing a semiconductor device according to some example embodiments of the present inventive concepts.

FIG. 15 illustrates a plan view showing a semiconductor device according to some example embodiments of the present inventive concepts.

FIG. 16 illustrates a cross-sectional view taken along line VIII-VIII′ of FIG. 15, showing a semiconductor device according to some example embodiments of the present inventive concepts.

### DETAILED DESCRIPTION

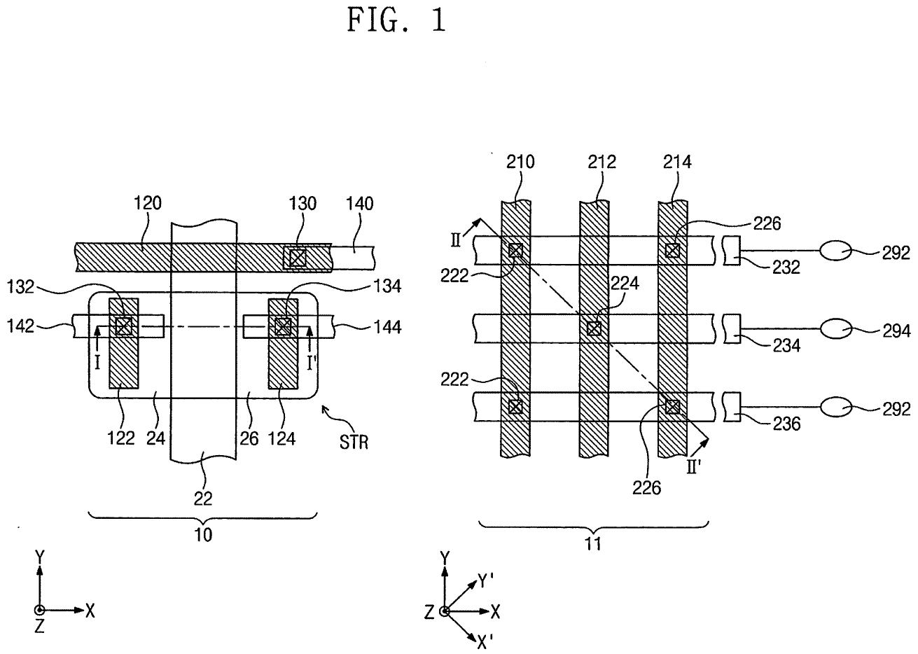

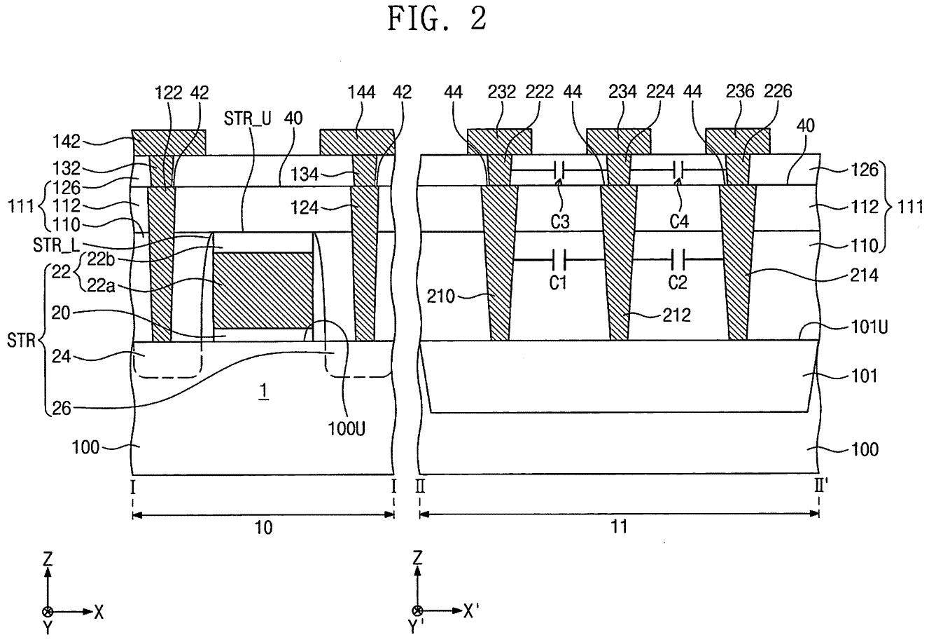

FIG. 1 illustrates a plan view showing a semiconductor device according to some example embodiments of the present inventive concepts. FIG. 2 illustrates a cross-sectional view taken along lines I-I′ and II-II′ of FIG. 1, showing a semiconductor device according to some example embodiments of the present inventive concepts.

Referring to FIGS. 1 and 2, a device isolation layer 101 may be disposed (e.g., located) in a substrate 100. The substrate 100 may be a silicon substrate, a silicon-germanium substrate, or a silicon-on-insulator (SOI) substrate. The substrate 100 may include a first region 10 and a second region 11. For example, the first region 10 may be a first peripheral circuit area, and the second region 11 may be a second peripheral circuit area. The first peripheral circuit area may include with switching transistors that drive memory elements. No switching transistors may be disposed on the second peripheral circuit area. The second peripheral circuit area may include a decoupling capacitor, dummy patterns, and/or dummy transistors. For another example, the first region 10 may be a cell array area, and the second region 11 may be a peripheral circuit area. The first region 10 may include memory elements and switching transistors that drive the memory elements. The peripheral circuit area may include a decoupling capacitor, dummy patterns, dummy transistors, and/or switching transistors that drive memory elements.

The device isolation layer 101 may be disposed on the second region 11 of the substrate 100. Although not shown, the device isolation layer 101 may be disposed to extend onto the first region 10 of the substrate 100. The device isolation layer 101 may define an active region 1 on the first region 10 of the substrate 100. The device isolation layer 101 may include a dielectric material, such as a silicon oxide layer. A switching transistor STR may be disposed on (e.g., directly on) the first region 10 of the substrate 100, for example such that the switching transistor STR may be in direct contact with the first region 10 of the substrate 100. For example, the switching transistor STR may be placed on the active region 1 of the substrate 100. The switching transistor STR may include a gate dielectric layer 20, a gate electrode 22, a first source/drain region 24, and a second source/drain region 26. In some example embodiments, one of the source/drain regions 24, 26 may be omitted. The gate electrode 22 may be disposed on the active region 1 of the substrate 100 and thus may be on (e.g., indirectly on) the first region 10 of the substrate 100. The gate electrode 22 may include a gate metal pattern 22a and a gate capping pattern 22b. The gate capping pattern 22b may be disposed on a top surface of the gate metal pattern 22a. The gate metal pattern 22a may include a metallic material, and the gate capping pattern 22b may include a dielectric material. The gate dielectric layer 20 may be disposed between the gate electrode 22 and the substrate 100. The gate dielectric layer 20 may include a thermal oxide layer (e.g., a silicon oxide layer) or a high-k dielectric layer (e.g., an aluminum oxide layer or a hafnium oxide layer). As shown in FIGS. 1-2, the first and second source/drain regions 24 and 26 may be disposed in the active region 1 of the substrate 100, and thus on the first region 10 of the substrate 100, on opposite sides of the gate electrode 22. The first source/drain region 24 may be disposed in the active region 1 of the substrate 100 on one side of the gate electrode 22, and the second source/drain region 26 may be disposed in the active region 1 of the substrate 100 on an opposite side of the gate electrode 22 such that the first and second source/drain regions 24 and 26 are understood to be on opposite sides of the gate electrode 22. The first and second source/drain regions 24 and 26 may be doped with impurities having a different conductivity type from that of the substrate 100.

A first interlayer dielectric layer 110 may be disposed (e.g., located) on the first and second regions 10 and 11 of the substrate 100. The first interlayer dielectric layer 110 may cover, and may be in direct contact with, a top surface 100U of the substrate 100, lateral surfaces STR_L of the switching transistor STR, a top surface STR_U of the switching transistor STR, and a top surface 101U of the device isolation layer 101. Accordingly, it will be understood that the first interlayer dielectric layer 110 may at least partially cover the switching transistor STR and may be on the second region 11 of the substrate 100. The first interlayer dielectric layer 110 may expose (e.g., may not cover in the vertical direction, or Z-direction, that extends perpendicular to the top surface 100U of the substrate 100) the top surface STR_U of the switching transistor STR. The first interlayer dielectric layer 110 may include a dielectric material, such as a silicon oxide layer. A second interlayer dielectric layer 112 may be disposed on the first interlayer dielectric layer 110, so as to be on (e.g., indirectly on, isolated from direct contact with by at least interposing first interlayer dielectric layer 110) the second region 11 of the substrate 100). The second interlayer dielectric layer 112 may cover a top surface 110U of the first interlayer dielectric layer 110 and the top surface STR_U of the switching transistor STR. Accordingly, the second interlayer dielectric layer 112 may be understood to cover the switching transistor STR and to be on the second region 11 of the substrate 100. The second interlayer dielectric layer 112 may include a dielectric material, such as a silicon oxide layer. In some example embodiments, the first and second interlayer dielectric layers 110 and 112 may be referred to as a single interlayer dielectric layer 111 that covers the switching transistor STR (e.g., such that no surfaces of the switching transistor STR are exposed by the interlayer dielectric layer 111) and is on the second region 11 of the substrate 100 (e.g., directly on the device isolation layer 101). In some example embodiments, the single interlayer dielectric layer 111 may be a single, continuous layer with no separate first and second interlayer dielectric layers 110 and 112.

As shown in FIG. 1, a first cell contact 120 may be disposed on the gate electrode 22 (e.g., in the Z-direction, also referred to herein as a vertical direction). The first cell contact 120 may penetrate (e.g., extend partially or completely through) the gate capping pattern 22b and the second interlayer dielectric layer 112 (e.g., in a horizontal that is parallel to the top surface 100U of the substrate 100, such as the X-direction), and may be in contact with and electrically connected to the gate metal pattern 22a. Accordingly, it will be understood that the cell contact 120 may penetrate the second interlayer dielectric layer 112 (and/or the single interlayer dielectric layer 111) on the first region 10 of the substrate 100 (e.g., directly or indirectly on the top surface 100U of the substrate 100) and may be in contact (e.g., direct contact) with the switching transistor STR. When viewed in plan, as shown in FIG. 1, the first cell contact 120 may be placed on one end of the gate electrode 22 and may extend in a first direction X (X-direction). The first cell contact 120 may have a bar shape extending in the first direction X. A top surface of the first cell contact 120 and a top surface 40 of the second interlayer dielectric layer 112 may be located at the same level from the top surface 100U of the substrate 100. The first cell contact 120 may include a metallic material, such as tungsten. A second cell contact 122 may penetrate the first and second interlayer dielectric layers 110 and 112 (e.g., the single interlayer dielectric layer 111), for example penetrate in a vertical direction (e.g., the Z-direction) and contact (e.g., directly contact) the first source/drain region 24, and a third cell contact 124 may penetrate the first and second interlayer dielectric layers 110 and 112 e.g., the single interlayer dielectric layer 111), for example penetrate in a vertical direction (e.g., the Z-direction) and contact (e.g., directly contact) the second source/drain region 26. Accordingly, it will be understood that the semiconductor device shown in FIG. 1 includes a cell contact, which may penetrate the interlayer dielectric layer (e.g., 111) on the first region 10 of the substrate 100 and in contact with the switching transistor STR, where the cell contact (e.g., 120, 122, or 124) is in contact with one of the gate electrode 22 or one of the first or second source/drain regions 24 or 26. The second cell contact 122 may be electrically connected to the first source/drain region 24, and the third cell contact 124 may be electrically connected to the second source/drain region 26. The second and third cell contacts 122 and 124 may have each of their top surfaces 42 at substantially the same level from the top surface 100U of the substrate 100 as that of the top surface 40 of the second interlayer dielectric layer 112 and that of the top surface of the first cell contact 120. Restated, the top surfaces 42 of the second and third cell contacts 122 and 124, the top surface 40 of the second interlayer dielectric layer 112, and the top surface of the first cell contact 120 may be coplanar with each other. It will be understood that elements that are coplanar with each other, as described herein, may be substantially coplanar with each other, which may include elements that are coplanar within manufacturing tolerances and/or material tolerances. Each of the second and third cell contacts 122 and 124 may have a bar shape that extends in a second direction Y (e.g., Y-direction, also referred to herein as a second horizontal direction that is parallel to the top surface 100U of the substrate 100) intersecting (e.g., perpendicular to) the first direction X (e.g., X-direction, also referred to herein as a first horizontal direction that is parallel to the top surface 100U of the substrate 100). The second and third cell contacts 122 and 124 may be parallel to each other (e.g., may extend in parallel in the Z-direction). The second and third cell contacts 122 and 124 may include a metallic material, such as tungsten.

A first dummy contact 210, a second dummy contact 212, and a third dummy contact 214 may be disposed on (e.g., directly or indirectly on) the second region 11 of the substrate 100. The first, second, and third dummy contacts 210, 212, and 214 may be disposed adjacent to each other in the first direction X (X-direction, also referred to herein as a first horizontal direction) and may each extend in the second direction Y (Y-direction, also referred to herein as a second horizontal direction that intersects, e.g., may be perpendicular to, the first horizontal direction) and in parallel with each other. In some example embodiments, the third dummy contact 214 may be omitted. Each of the first, second, and third dummy contacts 210, 212, and 214 may have a bar shape extending in the second direction Y, as shown in FIGS. 1-2. The second dummy contact 212 may be disposed between the first dummy contact 210 and the third dummy contact 214. As shown in at least FIG. 2, the first, second, and third dummy contacts 210, 212, and 214 may penetrate the first and second interlayer dielectric layers 110 and 112 that are disposed on the second region 11 of the substrate 100 (e.g., may each extend in the Z-direction to penetrate the first and second interlayer dielectric layers 110 and 112, and/or the single interlayer dielectric layer 111, in the Z-direction). The first, second, and third dummy contacts 210, 212, and 214 may be in contact (“direct contact”) with the device isolation layer 101 (e.g., in contact with a top surface 101U of the device isolation layer 101) disposed on the second region 11 of the substrate 100. The first, second, and third dummy contacts 210, 212, and 214 may be isolated from direct contact with the substrate 100 by at least the device isolation layer 101. For example, the first, second, and third dummy contacts 210, 212, and 214 may be electrically separated (“electrically isolated”, “isolated from electrical contact” and/or “isolated from direct contact”) and/or physically separated (“physically isolated”, “isolated from physical contact”, and/or “isolated from direct contact”) from the substrate 100, for example by at least the device isolation layer 101. Where the third dummy contact 214 is omitted, the first and second dummy contacts 210 and 212 may be electrically separated (“electrically isolated”, “isolated from electrical contact” and/or “isolated from direct contact”) and/or physically separated (“physically isolated”, “isolated from physical contact”, and/or “isolated from direct contact”) from the substrate 100, for example by at least the device isolation layer 101. The first, second, and third dummy contacts 210, 212, and 214 may have their top surfaces 44 at substantially the same level from the top surface 101U of the device isolation layer 101 and the top surface 100U of the substrate 100 as that of the top surfaces 42 of the first, second, and third cell contacts 120, 122, and 124. Restated, the top surfaces 44 of the first, second, and third dummy contacts 210, 212, and 214 and the top surfaces 42 of the first, second, and third cell contacts 120, 122, and 124 may be coplanar with each other. In some example embodiments, the top surface of the cell contact 120 may be coplanar with a top surface 40 of the second interlayer dielectric layer 112 and with top surfaces 44 of each of the first, second, and third dummy contacts 210, 212, and 214. Where the third dummy contact 214 is omitted, the top surfaces 44 of the first and second dummy contacts 210 and 212 and the top surface 42 of a cell contact (e.g., 122 and/or 124) that penetrates an interlayer dielectric layer (e.g., 110 and/or 112) may be coplanar with each other. The first, second, and third dummy contacts 210, 212, and 214 may include substantially the same material as that of the first, second, and third cell contacts 120, 122, and 124. For example, the first, second, and third dummy contacts 210, 212, and 214 may include a metallic material, such as tungsten.

A third interlayer dielectric layer 126 may be disposed on the second interlayer dielectric layer 112. The third interlayer dielectric layer 126 may cover the top surfaces 42 of the first, second, and third cell contacts 120, 122, and 124, and also cover the top surfaces 44 of the first, second, and third dummy contacts 210, 212, and 214. The third interlayer dielectric layer 126 may include a dielectric material, such as a silicon oxide layer. Some or all of the first, second, and third interlayer dielectric layers 110, 112, 126 may collectively be referred to as a single interlayer dielectric layer 111.

A first via 130 may penetrate the third interlayer dielectric layer 126 and may be disposed on the first cell contact 120. The first via 130 may be in contact with and electrically connected to the first cell contact 120. A second via 132 may penetrate the third interlayer dielectric layer 126 and may be disposed on the second cell contact 122. The second via 132 may be in contact with and electrically connected to the second cell contact 122. A third via 134 may penetrate the third interlayer dielectric layer 126 and may be disposed on the third cell contact 124. The third via 134 may be in contact with and electrically connected to the third cell contact 124. The first, second, and third vias 130, 132, and 134 may include a metallic material, such as tungsten.

First dummy vias 222 may penetrate the third interlayer dielectric layer 126 and may be disposed on the first dummy contact 210. The first dummy vias 222 may be in contact with and electrically connected to the first dummy contact 210. The first dummy vias 222 may be spaced apart from each other in the second direction Y. A second dummy via 224 may penetrate the third interlayer dielectric layer 126 and may be disposed on the second dummy contact 212. The second dummy via 224 may be in contact with and electrically connected to the second dummy contact 212. The second dummy via 224 may not be aligned in the first direction X with the first dummy vias 222. For example, the first dummy vias 222 and the second dummy via 224 may be arranged in a zigzag shape along the second direction Y. Accordingly, as shown in FIGS. 1 and 2, one first dummy via 222 may be directly between (e.g., in contact with each of, at opposite sides) a first dummy conductive line 232 and the first dummy contact 210, and another first dummy via 222 may be directly between a third dummy conductive line 236 and the first dummy contact 210, while second dummy via 224 may be directly between a second dummy conductive line 234 and the second dummy contact 212, such that, when viewed in plan, the one first dummy via 222 may face in the second direction Y toward the other first dummy via 222, and the first dummy vias 222 and the second dummy via 224 are arranged in a zigzag shape along the first and second directions X and Y. It will be understood that structures arranged in a “zigzag” shape may be arranged in a pattern of line segments or points that alternate between two parallel lines. Accordingly, the first and second dummy vias 222 and 224 that are arranged in the zigzag shape along the first and second directions X and Y will be understood to define points of a pattern that alternates between two parallel lines defined by the first and second dummy contact lines 210 and 212. Third dummy vias 226 may penetrate the third interlayer dielectric layer 126 and may be disposed on the third dummy contact 214. The third dummy vias 226 may be in contact with and electrically connected to the third dummy contact 214. The third dummy vias 226 may be spaced apart from each other in the second direction Y. The first dummy vias 222 may face in the first direction X toward the third dummy vias 226. The third dummy vias 226 may not be aligned in the first direction X with the second dummy via 224. For example, the third dummy vias 226 and the second dummy via 224 may be arranged in a zigzag shape along the second direction Y.

A first conductive line 140 may be disposed on the first via 130. The first conductive line 140 may be placed on the third interlayer dielectric layer 126, and may be in contact with and electrically connected to the first via 130. The first conductive line 140 is illustrated to extend in the first direction X, but the present inventive concepts are not limited thereto. A second conductive line 142 may be disposed on the second via 132. The second conductive line 142 may be disposed on the third interlayer dielectric layer 126, and may be in contact with and electrically connected to the second via 132. The second conductive line 142 is illustrated to extend in the first direction X, but the present inventive concepts are not limited thereto. A third conductive line 144 may be disposed on the third via 134. The third conductive line 144 may be placed on the third interlayer dielectric layer 126, and may be in contact with and electrically connected to the third via 134. The third conductive line 144 is illustrated to extend in the first direction X, but the present inventive concepts are not limited thereto. The first, second, and third conductive lines 140, 142, and 144 may include a metallic material, such as tungsten.

The first dummy conductive line 232 may be disposed on the third interlayer dielectric layer 126. As shown in FIG. 1, the first dummy conductive line 232 may be placed on (e.g., directly on, so as to be in direct contact with) both one first dummy via 222 and one third dummy via 226 that face each other in the first direction X. Accordingly, and as shown in FIG. 1, the first dummy conductive line 232 may be in contact with and electrically connected to each of the one first dummy via 222 and the one third dummy via 226 that face each other in the first direction X. As a result, it will be understood that the first dummy conductive line 232 may be on the interlayer dielectric layer 111 and may be electrically connected, through separate, respective dummy vias 222, 226, to both the first dummy contact 210 and the third dummy contact 214. The first dummy conductive line 232 may extend in the first direction X and run (“extend”) across (e.g., over, in the Z-direction) the first, second, and third dummy contacts 210, 212, and 214. The second dummy conductive line 234 may be disposed on the third interlayer dielectric layer 126. The second dummy conductive line 234 may be placed on (e.g., directly on, so as to be in direct contact with) the second dummy via 224. Accordingly, and as shown in FIG. 1, the second dummy conductive line 234 may be in contact with and electrically connected to the second dummy via 224. As a result, it will be understood that the second dummy conductive line 234 may be on the interlayer dielectric layer 111 and may be electrically connected, through the second dummy vias 224, to the second dummy contact 212. The second dummy conductive line 234 may extend in the first direction X and run across the first, second, and third dummy contacts 210, 212, and 214. The second dummy conductive line 234 may be parallel to the first dummy conductive line 232 and may be adjacent in the second direction Y to the first dummy conductive line 232. Accordingly, it will be understood that the first dummy conductive line 232 and the second dummy conductive line 234 may each extend in the first direction X (“first horizontal direction”) and in parallel with each other. The third dummy conductive line 236 may be disposed on the third interlayer dielectric layer 126. The third dummy conductive line 236 may be in contact with and electrically connected to other first dummy via 222 and other third dummy via 226 that face each other in the first direction X, such that the other third dummy via 226 may be directly between the third dummy conductive line 236 and the third dummy contact 214. The third dummy conductive line 236 may extend in the first direction X and run across the first, second, and third dummy contacts 210, 212, and 214. The third dummy conductive line 236 may be parallel to the first and second dummy conductive lines 232 and 234, and may be adjacent in the second direction Y to the second dummy conductive line 234. For example, the second dummy conductive line 234 may be disposed between the first dummy conductive line 232 and the third dummy conductive line 236. In some example embodiments, the first, second and third dummy vias 222, 224, and 226 may be absent, and the first, second, and third dummy conductive lines 232, 234, 236 may be in direct contact with one or more of the first, second, and third dummy contacts 210, 212, 214 (e.g., the first dummy conductive line 232 may extend over and in direct contact with the first and third dummy contacts 210 and 214, and the second dummy conductive line 234 may extend over and in direct contact with the second dummy contact 212).

In some example embodiments, a first voltage may be applied to the first dummy conductive line 232 and the third dummy conductive line 236, and a second voltage may be applied to the second dummy conductive line 234. The first voltage may be one of a power voltage (Vss or positive voltage) or a ground voltage (Vdd or negative voltage), and the second voltage may be the other of the power voltage or the ground voltage. Restated, the first dummy conductive line 232 may be electrically connected to a first voltage source 292 and the second dummy conductive line 234 may be electrically connected to a second voltage source 294, where the first voltage source 292 is configured to supply a first voltage, which may be one of a power voltage or a ground voltage, and the second voltage source 294 is configured to supply a second voltage, which may be another of the power voltage or the ground voltage, such that the first dummy conductive line 232 may be configured to receive the first voltage from the first voltage source 292 and the second dummy conductive line 234 may be configured to receive the second voltage from the second voltage source 294. A voltage source as described herein may be any well-known voltage source configured to supply a constant voltage, including a mains power supply. As additionally shown, the third dummy conductive line 236 may be electrically connected to the first voltage source 292. The first voltage may be applied through the first and third dummy vias 222 and 226 to the first and third dummy contacts 210 and 214 connected to the first and third dummy conductive lines 232 and 236. The second voltage may be applied through the second dummy via 224 to the second dummy contact 212 connected to the second dummy conductive line 234. Each of a first decoupling capacitor C1 and a second decoupling capacitor C2 may include a pair of electrodes and a dielectric layer between the pair of electrodes. For example, the first decoupling capacitor C1 may include the first dummy contact 210 and the second dummy contact 212 that constitute a pair of electrodes, and also include the first and second interlayer dielectric layers 110 and 112 that constitute a dielectric layer. Restated, the first dummy contact 210 and the second dummy contact 212 may constitute opposing electrodes of a first decoupling capacitor C1, such that the first dummy contact 210 constitutes a first electrode and the second dummy contact 212 constitutes a second electrode that opposes the first electrode. For example, the second decoupling capacitor C2 may include the second dummy contact 212 and the third dummy contact 214 that constitute a pair of electrodes, and also include the first and second interlayer dielectric layers 110 and 112 that constitute a dielectric layer. Restated, the second dummy contact 212 and the third dummy contact 214 may constitute opposing electrodes of a second decoupling capacitor C2, such that the second dummy contact 212 constitutes a first electrode and the third dummy contact 214 constitutes a second electrode that opposes the first electrode. The second dummy contact 212 may be used as a common electrode for the first and second decoupling capacitors C1 and C2.

In some example embodiments, the first voltage may be applied to the first and third dummy vias 222 and 226 connected to the first and third dummy conductive lines 232 and 236. The second voltage may be applied to the second dummy via 224 connected to the second dummy conductive line 234. Each of a third decoupling capacitor C3 and a fourth decoupling capacitor C4 may include a pair of electrodes (e.g., opposing electrodes) and a dielectric layer between the pair of electrodes. For example, the third decoupling capacitor C3 may include the first dummy via 222 and the second dummy via 224 that constitute a pair of opposing electrodes of the third decoupling capacitor C3, and also include the third interlayer dielectric layer 126 that constitutes a dielectric layer. For example, the fourth decoupling capacitor C4 may include the second dummy via 224 and the third dummy via 226 that constitute a pair of opposing electrodes of the fourth decoupling capacitor C4, and also include the third interlayer dielectric layer 126 that constitutes a dielectric layer. The second dummy via 224 may be used as a common electrode for the third and fourth decoupling capacitors C3 and C4.

According to some example embodiments of the present inventive concepts, to obtain uniformity of a surface that will be polished during a chemical mechanical polishing (CMP) process, when contacts and vias are formed on gate electrodes and source/drain regions of switching transistors, dummy contact and dummy vias may also be formed on empty regions of a substrate. A first voltage and a second voltage may be correspondingly applied to neighboring dummy contacts, and adjacent dummy vias may be provided thereon with corresponding dummy conductive lines that are capable of being supplied with the first and second voltages, which dummy conductive lines may constitute electrodes of decoupling capacitors. Therefore, unused dummy contacts and dummy vias may be utilized as electrodes of decoupling capacitors, and the formation of decoupling capacitors may improve electrical characteristics of a semiconductor device.

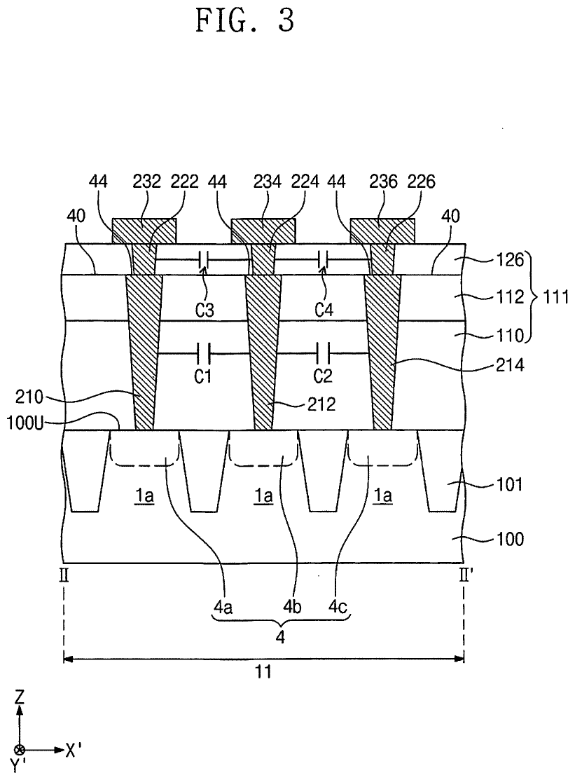

FIG. 3 illustrates a cross-sectional view taken along line II-II′ of FIG. 1, showing a semiconductor device according to some example embodiments of the present inventive concepts.

Referring to FIG. 3, the device isolation layers 101 may be disposed on the second region 11 of the substrate 100. The device isolation layers 101 may define dummy active regions 1a on the second region 11 of the substrate 100. Impurity regions 4 (e.g., first, second and third impurity regions 4a, 4b, 4c) may be disposed in the dummy active regions 1a and adjacent with each other in a first diagonal direction X′, that is parallel to a top surface 100U of the substrate 100 (e.g., the X′-direction), on the second region 11 of the substrate 100. It will be understood that a plurality of impurity regions 4 that are adjacent to each other in a first diagonal direction X′ may be arranged in a linear series extending in the first diagonal direction X′, such that, for example, the second impurity region 4b is adjacent to, and interposes between, the first and third impurity regions 4a and 4c. The device isolation layers 101 may physically separate adjacent impurity regions 4 from each other (e.g., isolate them from direct contact with each other). The impurity regions 4 may have the same conductive type as that of the first and second source/drain regions (see 24 and 26 of FIG. 2). The first, second, and third dummy contacts 210, 212, and 214 may be disposed to correspond to the impurity regions 4. The first, second, and third dummy contacts 210, 212, and 214 may contact the impurity regions 4. Accordingly, and for example as shown in FIG. 3, the first dummy contact 210 in the first interlayer dielectric layer 110 may be in contact with a first impurity region 4a, the second dummy contact 212 in the first interlayer dielectric layer 110 may be in contact with the second impurity region 4b, and the third dummy contact 214 in the first interlayer dielectric layer 110 may be in contact with the third impurity region 4c.

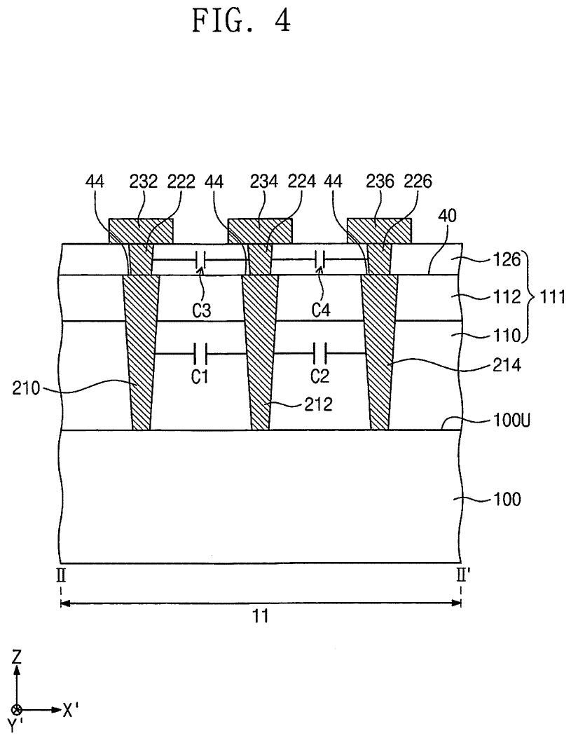

FIG. 4 illustrates a cross-sectional view taken along line II-II′ of FIG. 1, showing a semiconductor device according to some example embodiments of the present inventive concepts.

Referring to FIG. 4, the first, second, and third dummy contacts 210, 212, and 214 may contact the substrate 100. For example, on the second region 11, the first, second, and third dummy contacts 210, 212, and 214 may contact (“directly contact”) the top surface 100U of the substrate 100. The second region 11 of the substrate 100 may include no impurity regions, as illustrated in FIG. 3. Restated, the substrate 100 may not include any impurity regions in the second region 11. For example, in some example embodiments, including the example embodiments shown in FIG. 4, there may be no device isolation layer 101 shown in FIGS. 2 and 3 in the substrate 100. The first, second, and third dummy contacts 210, 212, and 214 may be electrically separated (“electrically isolated”) from the substrate 100.

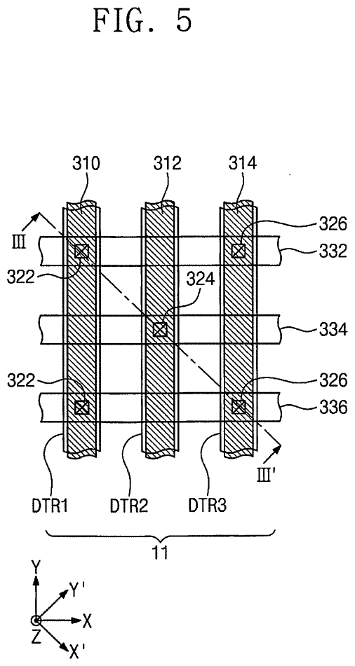

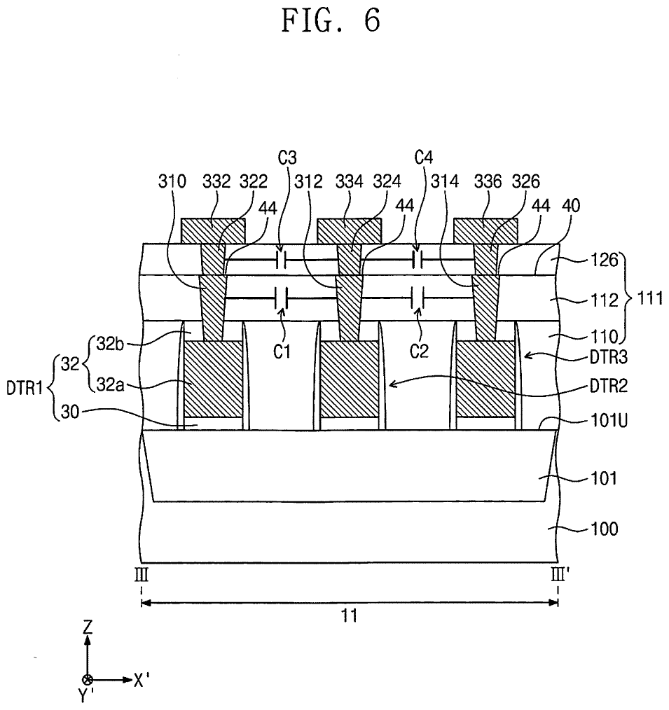

FIG. 5 illustrates a plan view showing a semiconductor device according to some example embodiments of the present inventive concepts. FIG. 6 illustrates a cross-sectional view taken along line III-III′ of FIG. 5, showing a semiconductor device according to some example embodiments of the present inventive concepts.

Referring to FIGS. 5 and 6, a first dummy transistor DTR1, a second dummy transistor DTR2, and a third dummy transistor DTR3 may be disposed on the second region 11 of the substrate 100. The first, second, and third dummy transistors DTR1, DTR2, and DTR3 may be placed on the device isolation layer 101 disposed on the second region 11 of the substrate 100. The first, second, and third dummy transistors DTR1, DTR2, and DTR3 may be adjacent to each other in the first direction X and may extend in the second direction Y. The second dummy transistor DTR2 may be disposed between the first dummy transistor DTR1 and the third dummy transistor DTR3. Each of the first, second, and third dummy transistors DTR1, DTR2, and DTR3 may include a dummy gate dielectric layer 30 and a dummy gate electrode 32. The dummy gate dielectric layer 30 may be disposed on the device isolation layer 101. The dummy gate dielectric layer 30 may include a thermal oxide layer (e.g., a silicon oxide layer) or a high-k dielectric layer (e.g., a hafnium oxide layer or an aluminum oxide layer). The dummy gate electrode 32 may be disposed on the dummy gate dielectric layer 30. The dummy gate electrode 32 may include a dummy gate metal pattern 32a and a dummy gate capping pattern 32b that are sequentially stacked on the dummy gate dielectric layer 30. The dummy gate metal pattern 32a may include the same material as that of the gate metal pattern 22a. The dummy gate capping pattern 32b may include the same material as that of the gate capping pattern 22b shown in FIG. 2. The first interlayer dielectric layer 110 may cover lateral surfaces of the first, second, and third dummy transistors DTR1, DTR2, and DTR3. The first interlayer dielectric layer 110 may expose a top surface of the dummy gate capping pattern 32b.

A first dummy contact 310 may be disposed on the first dummy transistor DTR1, a second dummy contact 312 may be disposed on the second dummy transistor DTR2, and a third dummy contact 314 may be disposed on the third dummy transistor DTR3. Accordingly, the first, second, and third dummy contacts 310, 312, and 314 may not fully penetrate the first interlayer dielectric layer 110 and thus may not fully penetrate the single interlayer dielectric layer 111. The first, second, and third dummy contacts 310, 312, and 314 may be adjacent to each other in the first direction X. The second dummy contact 312 may be disposed between the first dummy contact 310 and the third dummy contact 314. The first, second, and third dummy contacts 310, 312, and 314 may be parallel to each other. The first, second, and third dummy contacts 310, 312, and 314 may be electrically separated from the substrate 100.

The first dummy contact 310 may penetrate the second interlayer dielectric layer 112 and the dummy gate capping pattern 32b of the first dummy transistor DTR1, and may contact the dummy gate metal pattern 32a of the first dummy transistor DTR1. The first dummy contact 310 may extend in the second direction Y. The second dummy contact 312 may penetrate the second interlayer dielectric layer 112 and the dummy gate capping pattern 32b of the second dummy transistor DTR2, and may contact the dummy gate metal pattern 32a of the second dummy transistor DTR2. The second dummy contact 312 may extend in the second direction Y. The third dummy contact 314 may penetrate the second interlayer dielectric layer 112 and the dummy gate capping pattern 32b of the third dummy transistor DTR3, and may contact the dummy gate metal pattern 32a of the third dummy transistor DTR3. The third dummy contact 314 may extend in the second direction Y. The first, second, and third dummy contacts 310, 312, and 314 may have their top surfaces 44 at the same level from the top surface 101U of the device isolation layer 101 as that of the top surface 40 of the second interlayer dielectric layer 112. The first, second, and third dummy contacts 310, 312, and 314 may include a metallic material, such as tungsten.

First dummy vias 322 may be disposed on the first dummy contact 310. The first dummy vias 322 may penetrate the third interlayer dielectric layer 126 and have electrical connection with the first dummy contact 310. The first dummy vias 322 may be spaced apart from each other in the second direction Y on the first dummy contact 310. A second dummy via 324 may be disposed on the second dummy contact 312. The second dummy via 324 may penetrate the third interlayer dielectric layer 126, and may be in contact with and electrically connected to the second dummy contact 312. The second dummy via 324 may not be aligned in the first direction X with the first dummy vias 322. For example, the first dummy vias 322 and the second dummy via 324 may be arranged in a zigzag shape along the second direction Y. Third dummy vias 326 may be disposed on the third dummy contact 314. The third dummy vias 326 may penetrate the third interlayer dielectric layer 126, and may be in contact with and electrically connected to the third dummy contact 314. The third dummy vias 326 may be spaced apart from each other in the second direction Y on the third dummy contact 314. The third dummy vias 326 may face in the first direction X toward the first dummy vias 322. The second dummy via 324 and the third dummy vias 326 may be arranged in a zigzag shape along the second direction Y.

A first dummy conductive line 332 may be disposed on the third interlayer dielectric layer 126. The first dummy conductive line 332 may be placed on one first dummy via 322 and one third dummy via 326 that face each other in the first direction X. The first dummy conductive line 332 may be in contact with and electrically connected to the one first dummy via 322 and the one third dummy via 326 that face each other in the first direction X. The first dummy conductive line 332 may extend in the first direction X, while running across the first, second, and third dummy contacts 310, 312, and 314 and the first, second, and third dummy transistors DTR1, DTR2, and DTR3. A second dummy conductive line 334 may be disposed on the third interlayer dielectric layer 126. The second dummy conductive line 334 may be placed on the second dummy via 324. The second dummy conductive line 334 may be in contact with and electrically connected to the second dummy via 324. The second dummy conductive line 334 may extend in the first direction X, while running across the first, second, and third dummy contacts 310, 312, and 314 and the first, second, and third dummy transistors DTR1, DTR2, and DTR3. The second dummy conductive line 334 may be parallel to the first dummy conductive line 332 and may be adjacent in the second direction Y to the first dummy conductive line 332. A third dummy conductive line 336 may be disposed on the third interlayer dielectric layer 126. The third dummy conductive line 336 may be in contact with and electrically connected to other first dummy via 322 and other third dummy via 326 that face each other in the first direction X. The third dummy conductive line 336 may extend in the first direction X, while running across the first, second, and third dummy contacts 310, 312, and 314 and the first, second, and third dummy transistors DTR1, DTR2, and DTR3. The third dummy conductive line 336 may be parallel to the first and second dummy conductive lines 332 and 334, and may be adjacent in the second direction Y to the second dummy conductive line 334. For example, the second dummy conductive line 334 may be disposed between the first dummy conductive line 332 and the third dummy conductive line 336.

In some example embodiments, a first voltage may be applied to the first dummy conductive line 332 and the third dummy conductive line 336, and a second voltage may be applied to the second dummy conductive line 334. The first voltage may be one of a power voltage (Vss or positive voltage) and a ground voltage (Vdd or negative voltage), and the second voltage may be the other of the power voltage and the ground voltage. The first voltage may be applied through the first and third dummy vias 322 and 326 to the first and third dummy contacts 310 and 314 connected to the first and third dummy conductive lines 332 and 336. The second voltage may be applied through the second dummy via 324 to the second dummy contact 312 connected to the second dummy conductive line 334. A first decoupling capacitor C1 may include the first dummy contact 310 and the second dummy contact 312 that constitute a pair of electrodes, and also include the second interlayer dielectric layer 112 that constitutes a dielectric layer. A second decoupling capacitor C2 may include the second dummy contact 312 and the third dummy contact 314 that constitute a pair of electrodes, and also include the second interlayer dielectric layer 112 that constitutes a dielectric layer. The second dummy contact 312 may be used as a common electrode for the first and second decoupling capacitors C1 and C2. A third decoupling capacitor C3 may include the first dummy via 322 and the second dummy via 324 that constitute a pair of electrodes, and also include the third interlayer dielectric layer 126 that constitutes a dielectric layer. A fourth decoupling capacitor C4 may include the second dummy via 324 and the third dummy via 326 that constitute a pair of electrodes, and also include the third interlayer dielectric layer 126 that constitutes a dielectric layer. The second dummy via 324 may be used as a common electrode for the third and fourth decoupling capacitors C3 and C4.

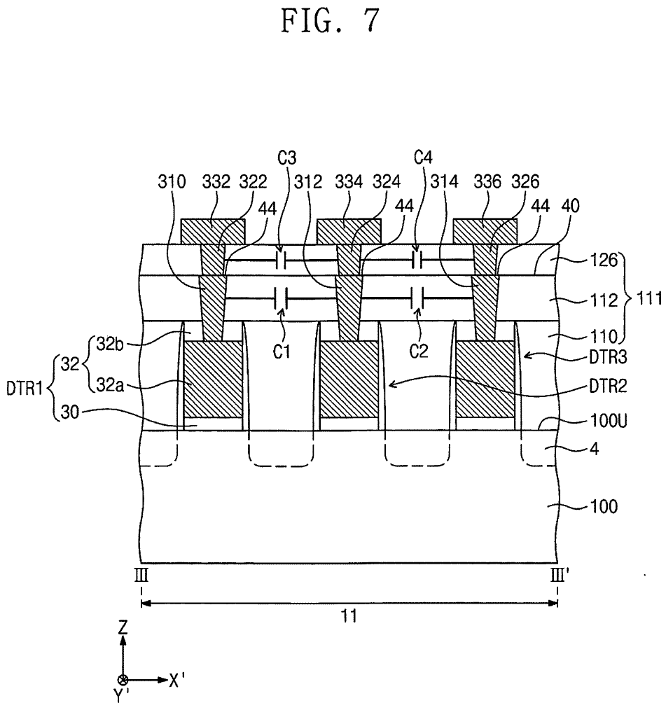

FIG. 7 illustrates a cross-sectional view taken along line III-III′ of FIG. 5, showing a semiconductor device according to some example embodiments of the present inventive concepts.

Referring to FIG. 7, the impurity regions 4 may be disposed on the second region 11 of the substrate 100. The impurity regions 4 may be placed on the second region 11 of the substrate 100 on one side of the first dummy transistor DTR1, on the second region 11 of the substrate 100 between the first, second, and third dummy transistors DTR1, DTR2, and DTR3, and on the second region 11 of the substrate 100 on one side of the third dummy transistor DTR3. The impurity regions 4 may have the same conductive type as that of the first and second source/drain regions (see 24 and 26 of FIG. 2).

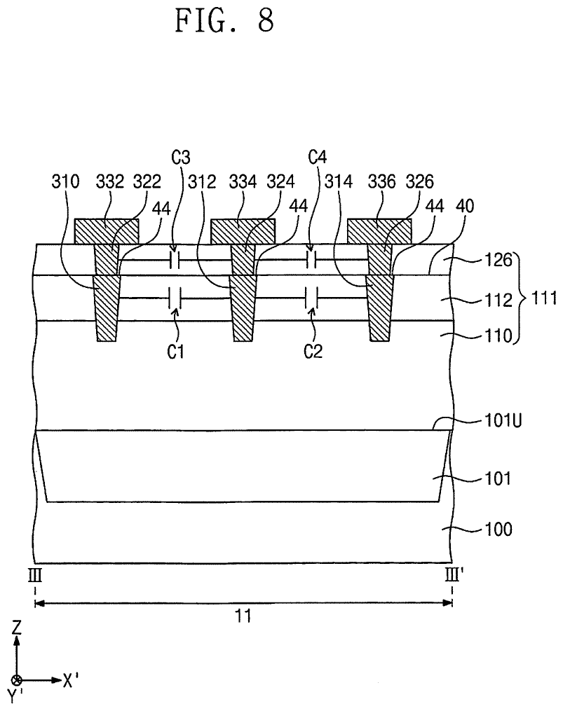

FIG. 8 illustrates a cross-sectional view taken along line III-III′ of FIG. 5, showing a semiconductor device according to some example embodiments of the present inventive concepts.

Referring to FIG. 8, there may be none of the first, second, and third dummy transistors DTR1, DTR2, and DTR3 discussed in FIGS. 5 and 6. In this case, the first, second, and third dummy contacts 310, 312, and 314 may penetrate the second interlayer dielectric layer 112 and may be disposed on the first interlayer dielectric layer 110. As shown, the first, second, and third dummy contacts 310, 312, and 314 may not fully penetrate through the first interlayer dielectric layer 110 and thus may not fully penetrate through the single interlayer dielectric layer 111. The first, second, and third dummy contacts 310, 312, and 314 may have their bottom surfaces in contact with the first interlayer dielectric layer 110. The bottom surfaces of the first, second, and third dummy contacts 310, 312, and 314 may be located at their levels higher than that of the top surface 100U of the substrate 100 and that of the top surface 101U of the device isolation layer 101. The first, second, and third dummy contacts 310, 312, and 314 may not contact the substrate 100 or the device isolation layer 101. For example, the first, second, and third dummy contacts 310, 312, and 314 may be electrically separated from the substrate 100.

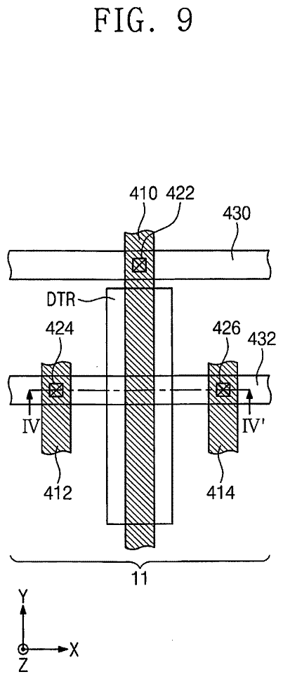

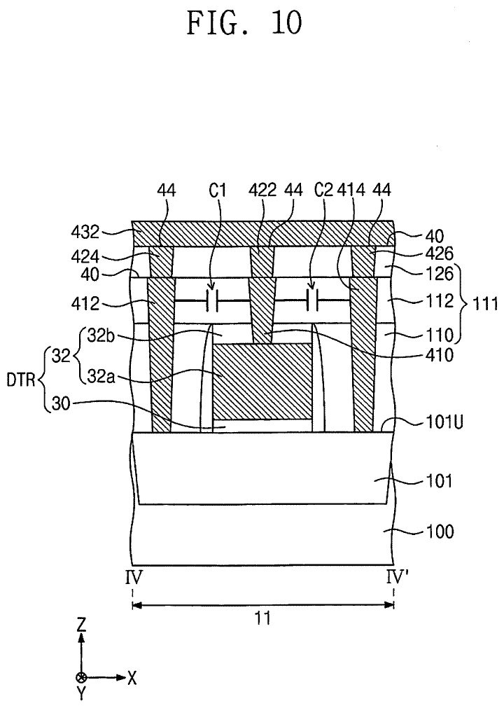

FIG. 9 illustrates a plan view showing a semiconductor device according to some example embodiments of the present inventive concepts. FIG. 10 illustrates a cross-sectional view taken along line IV-IV′ of FIG. 9, showing a semiconductor device according to some example embodiments of the present inventive concepts.

Referring to FIGS. 9 and 10, a dummy transistor DTR may be disposed on the device isolation layer 101 on the second region 11 of the substrate 100. The dummy transistor DTR may include a dummy gate dielectric layer 30 and a dummy gate electrode 32 that are sequentially stacked on the device isolation layer 101. The dummy gate electrode 32 may include a dummy gate metal pattern 32a and a dummy gate capping pattern 32b that are sequentially stacked on the dummy gate dielectric layer 30. Accordingly, it will be understood that the dummy transistor DTR may include a dummy gate dielectric layer 30 on the second region 11 of the substrate 100, a dummy gate metal pattern 32a on the dummy gate dielectric layer 30, and a dummy gate capping pattern 32b on the dummy gate metal pattern 32a. The dummy transistor DTR may extend in the second direction Y. The first interlayer dielectric layer 110 may cover lateral surfaces of the dummy transistor DTR. The first interlayer dielectric layer 110 may expose a top surface of the dummy gate capping pattern 32b. The second interlayer dielectric layer 112 may be disposed on the first interlayer dielectric layer 110. The second interlayer dielectric layer 112 may cover the top surface of the dummy gate capping pattern 32b and the top surface of the first interlayer dielectric layer 110.

A first dummy contact 410 may be disposed on the dummy transistor DTR, such that the dummy transistor DTR may be understood to be between the first dummy contact 410 and the second region 11 of the substrate 100. The first dummy contact 410 may penetrate the second and first interlayer dielectric layers 112 and 110 and the dummy gate capping pattern 32b, and may contact the dummy gate metal pattern 32a. The first dummy contact 410 may extend in a direction in which the dummy transistor DTR extends. For example, the first dummy contact 410 may extend in the second direction Y. A second dummy contact 412 may be disposed on the device isolation layer 101 on a first side of the dummy transistor DTR. The second dummy contact 412 may penetrate the second and first interlayer dielectric layers 112 and 110, and may contact the top surface of the device isolation layer 101. The second dummy contact 412 may be disposed on a first side of the first dummy contact 410 and may extend in the first direction X. The second dummy contact 412 may extend in the second direction Y. For example, the second dummy contact 412 may be parallel in the second direction Y to the first dummy contact 410. A third dummy contact 414 may be disposed on the device isolation layer 101 on a second side of the dummy transistor DTR. The third dummy contact 414 may penetrate the second and first interlayer dielectric layers 112 and 110, and may contact the top surface of the device isolation layer 101. The third dummy contact 414 may be disposed on a second side of the first dummy contact 410 and may extend in the first direction X. The third dummy contact 414 may extend in the second direction Y. For example, the third dummy contact 414 may be parallel in the second direction Y to the first dummy contact 410 and the second dummy contact 412. The first, second, and third dummy contacts 410, 412, and 414 may have their top surfaces 44 at the same level from the top surface 101U of the device isolation layer 101 as that of the top surface 40 of the second interlayer dielectric layer 112. The first, second, and third dummy contacts 410, 412, and 414 may include a metallic material, such as tungsten.

A first dummy via 422 may be disposed on the first dummy contact 410. The first dummy via 422 may penetrate the third interlayer dielectric layer 126 and may be in contact with and electrically connected to the first dummy contact 410. A second dummy via 424 may be disposed on the second dummy contact 412. The second dummy via 424 may penetrate the third interlayer dielectric layer 126 and may be in contact with and electrically connected to the second dummy contact 412. A third dummy via 426 may be disposed on the third dummy contact 414. The third dummy via 426 may penetrate the third interlayer dielectric layer 126 and may be in contact with and electrically connected to the third dummy contact 414.

A first dummy conductive line 430 may be disposed on the third interlayer dielectric layer 126. The first dummy conductive line 430 may be placed on the first dummy via 422 and may extend in the first direction X. The first dummy conductive line 430 may contact a top surface of the first dummy via 422 and have electrical connection with the first dummy via 422. A second dummy conductive line 432 may be disposed on the third interlayer dielectric layer 126. The second dummy conductive line 432 may be placed on the second dummy via 424 and the third dummy via 426, and may extend in the first direction X. The second dummy conductive line 432 may run in the first direction X across the dummy transistor DTR. The second dummy conductive line 432 may contact top surfaces of the second and third dummy vias 424 and 426, and have electrical connection with the second and third dummy vias 424 and 426. The first dummy conductive line 430 and the second dummy conductive line 432 may be adjacent to each other in the second direction Y and parallel to each other in the first direction X. The first dummy conductive line 430 and the second dummy conductive line 432 may include a metallic material, such as tungsten.

In some example embodiments, a first voltage may be applied to the first dummy conductive line 430, and a second voltage may be applied to the second dummy conductive line 432. The first voltage may be one of a power voltage (Vss or positive voltage) and a ground voltage (Vdd or negative voltage), and the second voltage may be the other of the power voltage and the ground voltage. The first voltage may be applied through the second dummy via 424 to the first dummy contact 410 connected to the first dummy conductive line 430. The second voltage may be applied through the second and third dummy vias 424 and 426 to the second and third dummy contacts 412 and 414 connected to the second dummy conductive line 432. A first decoupling capacitor C1 may include the second dummy contact 412 and the first dummy contact 410 that constitute a pair of electrodes, and also include the first and second interlayer dielectric layers 110 and 112 that constitute a dielectric layer. A second decoupling capacitor C2 may include the first dummy contact 410 and the third dummy contact 414 that constitute a pair of electrodes, and also include the first and second interlayer dielectric layers 110 and 112 that constitute a dielectric layer. The first dummy contact 410 may be used as a common electrode for the first and second decoupling capacitors C1 and C2.

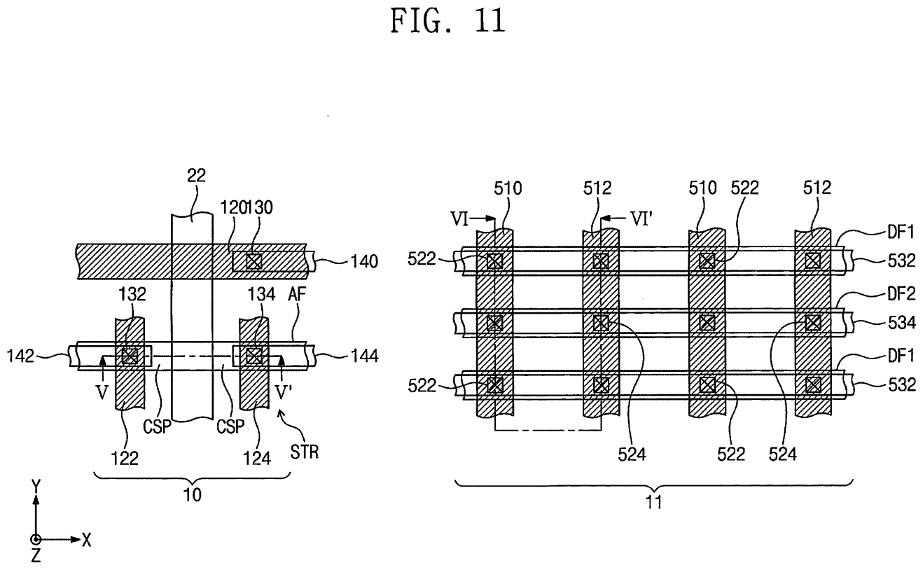

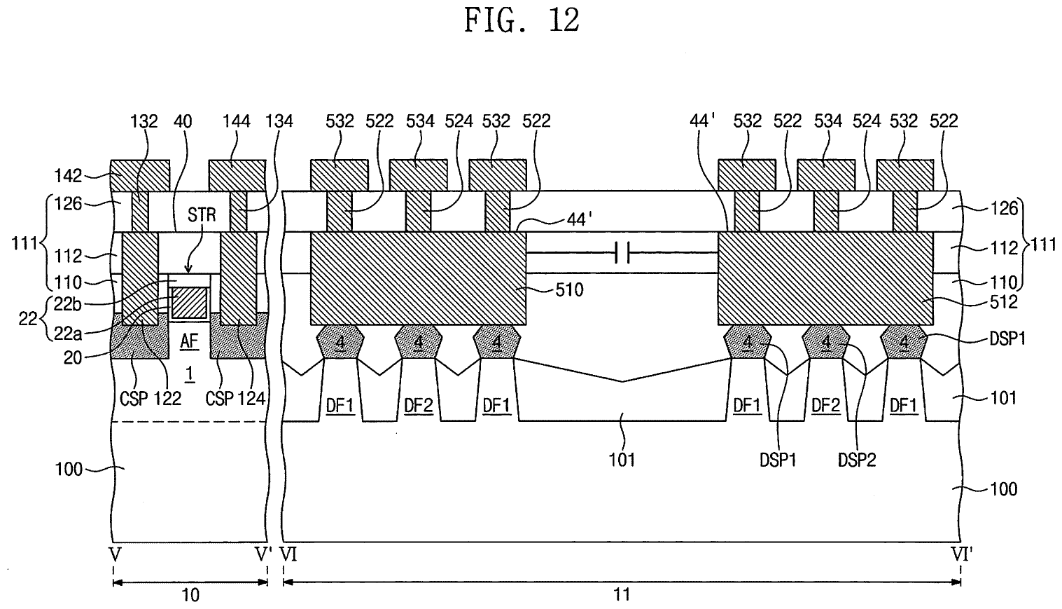

FIG. 11 illustrates a plan view showing a semiconductor device according to some example embodiments of the present inventive concepts. FIG. 12 illustrates a cross-sectional view taken along lines V-V′ and VI-VI′ of FIG. 11, showing a semiconductor device according to some example embodiments of the present inventive concepts.

Referring to FIGS. 11 and 12, a device isolation layer 101 may be disposed on a second region 11 of a substrate 100. The device isolation layer 101 may define an active region 1 on a first region 10 of the substrate 100. It will be understood that the device isolation layer 101 may be in the substrate 100. The substrate 100 may include an active fin AF disposed on the active region 1. The active fin AF may protrude from a top surface of the device isolation layer 101. The active fin AF may extend in a first direction X. A switching transistor STR may be disposed on the first region 10 of the substrate 100. A gate electrode 22 may extend in a second direction Y. A gate dielectric layer 20 may be disposed between a top surface of the active fin AF and a gate metal pattern 22a of the gate electrode 22, and may cover lateral surfaces of the gate metal pattern 22a. Cell semiconductor patterns CSP may be disposed on portions of the active fin AF that are exposed by the gate electrode 22. The portions of the active fin AF that are exposed by the gate electrode 22 may have their top surfaces at a lower level than that of top surface of the active fin AF. The cell semiconductor patterns CSP may be disposed on the top surfaces of the portions of the active fin AF and may be understood to be at opposite sides of the gate electrode 22. The cell semiconductor patterns CSP and gate electrode 22 may comprise a switching transistor STR on the first region 10 of the substrate 100. The cell semiconductor patterns CSP may be semiconductor patterns that are formed by an epitaxial growth process in which the substrate 100 is used as a seed. The cell semiconductor patterns CSP may correspond to the first and second source/drain regions 24 and 26 illustrated in FIGS. 1 and 2.

A first interlayer dielectric layer 110 may be disposed on the first region 10 of the substrate 100. The first interlayer dielectric layer 110 may cover the active fin AF, a lateral surface of the gate electrode 22, and the top surface of the device isolation layer 101. A second interlayer dielectric layer 112 may be disposed on the first interlayer dielectric layer 110. A first cell contact 120 may be disposed on one end of the gate electrode 22. The first cell contact 120 may run across the gate electrode 22 and extend in the second direction Y. The first cell contact 120 may penetrate the first and second interlayer dielectric layers 110 and 112 and a gate capping pattern 22b of the gate electrode 22, and may contact the gate metal pattern 22a. The first cell contact 120 may have a top surface at the same level from a top surface of the substrate 100 as that of a top surface 40 of the second interlayer dielectric layer 112. A second cell contact 122 may be disposed on one cell semiconductor pattern CSP. A third cell contact 124 may be disposed on other cell semiconductor pattern CSP. The second and third cell contacts 122 and 124 may penetrate the first and second interlayer dielectric layers 110 and 112, and may contact the cell semiconductor patterns CSP. It will thus be understood that the cell contacts 122 and 124 may be a plurality of first cell contacts that penetrate at least the first interlayer dielectric layer 110 and are in contact with separate, respective cell semiconductor patterns CSP, e.g., separate, respective source/drain regions, while the first cell contact 120 may be understood to be a separate cell contact that penetrates the first interlayer dielectric layer 110 and is in contact with the gate electrode 22. The top surface 40 of the second interlayer dielectric layer 112 may be located at the same level from the top surface of the substrate 100 as that of top surfaces 42 of the second and third cell contacts 122 and 124. Restated, top surfaces of first and second dummy contacts 510 and 512, and the top surfaces of the cell contacts 120, 122, 124 may be coplanar with each other, and may be coplanar with a top surface of the second interlayer dielectric layer 112.

A first via 130 may be disposed on the first cell contact 120, and a second via 132 may be disposed on the second cell contact 122. A third via 134 may be disposed on the third cell contact 124. A first conductive line 140 may be disposed on the first via 130, and may be electrically connected through the first via 130 to the first cell contact 120. A second conductive line 142 may be disposed on the second via 132, and may be electrically connected through the second via 132 to the second cell contact 122. A third conductive line 144 may be disposed on the third via 134, and may be electrically connected through the third via 134 to the third cell contact 124.

The device isolation layer 101 may extend onto the second region 11 of the substrate 100. The device isolation layer 101, still in the substrate 100, may define dummy active regions on the second region 11 of the substrate 100. Each of first and second dummy fins DF1 and DF2 may be disposed on a corresponding one of the dummy active regions. The first and second dummy fins DF1 and DF2 will be understood to be defined by the device isolation layer 101 and thus will be understood to be defined by the device isolation layer 101 on the second region 11 of the substrate 100, and may be arranged alternately and repeatedly (e.g., adjacent to each other) in the second direction Y that intersects the first direction X and may extend in parallel in the first direction X. First and second dummy semiconductor patterns DSP1 and DSP2 may be disposed on the first and second dummy fins DF1 and DF2. For example, one or a plurality of first dummy semiconductor patterns DSP1 may be disposed on corresponding first dummy fins DF1. One or a plurality of second dummy semiconductor patterns DSP2 may be disposed on corresponding second dummy fins DF2. When the first dummy semiconductor pattern DSP1 is provided in plural, the plurality of first dummy semiconductor patterns DSP1 may be spaced apart from each other in the first direction X on a top surface of each first dummy fin DF1. When the second dummy semiconductor pattern DSP2 is provided in plural, the plurality of second dummy semiconductor patterns DSP2 may be spaced apart from each other in the first direction X on a top surface of each second dummy fin DF2. The first and second dummy semiconductor patterns DSP1 and DSP2 that are adjacent to each other in the second direction Y may be spaced apart from each other in the second direction Y as illustrated in figures. In some example embodiments, the first and second dummy semiconductor patterns DSP1 and DSP2 that are adjacent to each other in the second direction Y may be in physical contact with each other to form a single dummy semiconductor pattern. The first and second dummy semiconductor patterns DSP1 and DSP2 may be semiconductor patterns that are formed by an epitaxial growth process in which the substrate 100 is used a seed. Impurity regions 4 may be provided in the first and second dummy semiconductor patterns DSP1 and DSP2. In some example embodiments, the impurity regions 4 may not be provided in the first dummy semiconductor pattern DSP1 or in the second dummy semiconductor pattern DSP2.

The first interlayer dielectric layer 110 may extend onto the second region 11 of the substrate 100. The first interlayer dielectric layer 110 may cover the first and second dummy semiconductor patterns DSP1 and DSP2 and also cover the top surface of the device isolation layer 101. The second interlayer dielectric layer 112 may be disposed on the first interlayer dielectric layer 110. First and second dummy contacts 510 and 512 may penetrate the second interlayer dielectric layer 112 and may be disposed in the first interlayer dielectric layer 110. The first and second dummy contacts 510 and 512 may contact the first and second dummy semiconductor patterns DSP1 and DSP2 that are adjacent to each other in the second direction Y. The first and second dummy contacts 510 and 512 may be arranged alternately and repeatedly in the first direction X. Each of the first and second dummy contacts 510 and 512 may have a bar shape extending in the second direction Y. The first and second dummy contacts 510 and 512 may be parallel to each other in the second direction Y. The first and second dummy contacts 510 and 512 may have their top surfaces 44′ at the same level from the top surface of the substrate 100 as that of the top surface 40 of the second interlayer dielectric layer 112. The first and second dummy contacts 510 and 512 may include a metallic material, such as tungsten. In some example embodiments, the first dummy contact 510 and the second dummy contact 512 that are adjacent in the first direction X may constitute electrodes of a decoupling capacitor.

A third interlayer dielectric layer 126 may extend onto the second interlayer dielectric layer 112 disposed on the second region 11 of the substrate 100. The third interlayer dielectric layer 126 may cover the top surfaces 44′ of the first and second dummy contacts 510 and 512 and also cover the top surface 40 of the second interlayer dielectric layer 112. First dummy vias 522 may be disposed on the first dummy contacts 510. The first dummy vias 522 may penetrate the third interlayer dielectric layer 126. The first dummy vias 522 may contact top surfaces of the first dummy contacts 510 and have electrical connection with the first dummy contacts 510. A plurality of first dummy vias 522 on one first dummy contact 510 may be spaced apart from each other in the second direction Y. A plurality of first dummy vias 522 on the first dummy contacts 510 spaced apart from each other in the first direction X may be disposed to face each other in the first direction X. Second dummy vias 524 may be disposed on the second dummy contacts 512. The second dummy vias 524 may penetrate the third interlayer dielectric layer 126. The second dummy vias 524 may contact top surfaces of the second dummy contacts 512 and have electrical connection with the second dummy contacts 512. A plurality of second dummy vias 524 on one second dummy contact 512 may be spaced apart from each other in the second direction Y. A plurality of second dummy vias 524 on the second dummy contacts 512 spaced apart from each other in the first direction X may be disposed to face each other in the first direction X. The second dummy vias 524 and the first dummy vias 522 may be disposed not to face each other in the first direction X. For example, the first dummy vias 522 and the second dummy via 524 may be arranged in a zigzag shape along the first and second directions X and Y. The first and second dummy vias 522 and 524 may include a metallic material, such as tungsten.

First dummy conductive lines 532 may be disposed on the third interlayer dielectric layer 126. The first dummy conductive lines 532 may extend in the first direction X on the first dummy fins DF1. The first dummy conductive lines 532 may contact the first dummy vias 522 that face each other in the first direction X. The first dummy conductive lines 532 may be electrically connected through the first dummy vias 522 to the first dummy contacts 510. The first dummy conductive lines 532 may be arranged in the second direction Y. Second dummy conductive lines 534 may be disposed on the third interlayer dielectric layer 126. The second dummy conductive lines 534 may extend in the first direction X on the second dummy fins DF2. The second dummy conductive lines 534 may contact the second dummy vias 524 that face each other in the first direction X. The second dummy conductive lines 534 may be electrically connected through the second dummy vias 524 to the second dummy contacts 512. The second dummy conductive lines 534 may be arranged in the second direction Y. For example, the first dummy conductive lines 532 and the second dummy conductive lines 534 may be arranged alternately and repeatedly in the second direction Y.

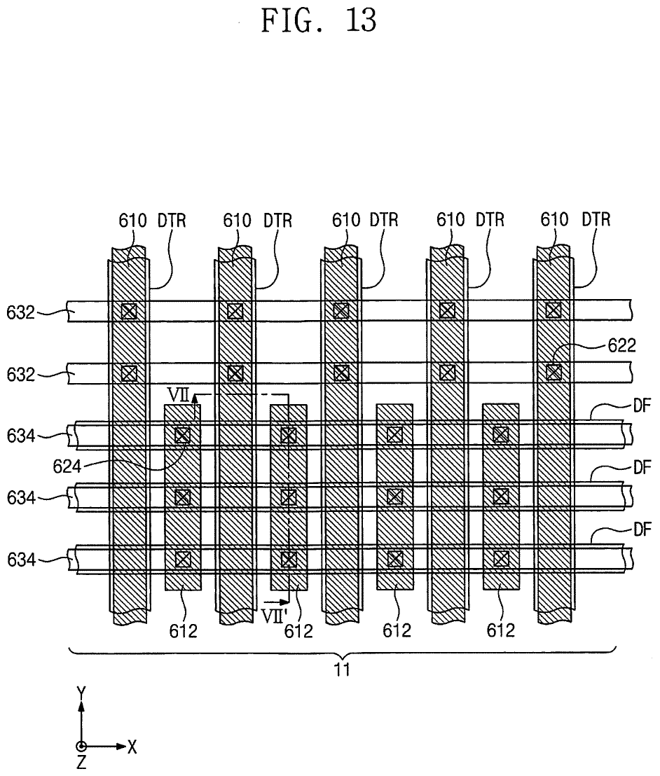

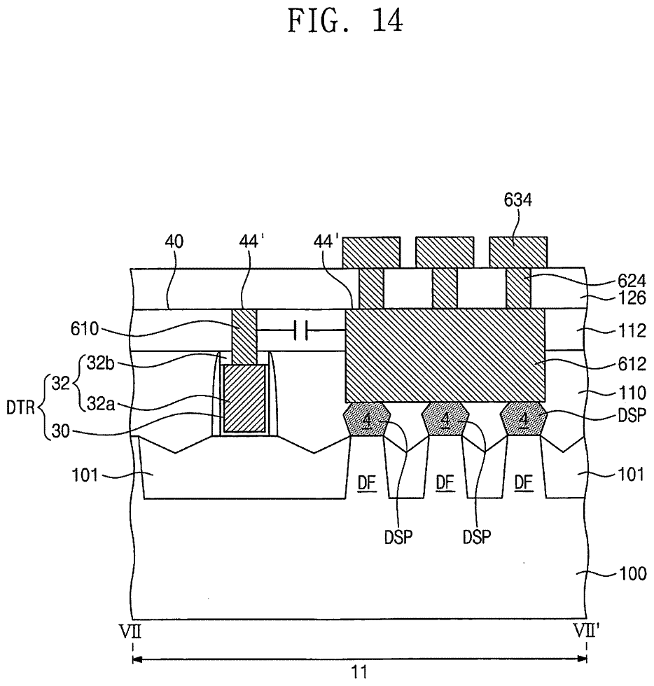

FIG. 13 illustrates a plan view showing a semiconductor device according to some example embodiments of the present inventive concepts. FIG. 14 illustrates a cross-sectional view taken along line VII-VII′ of FIG. 13, showing a semiconductor device according to some example embodiments of the present inventive concepts.

Referring to FIGS. 13 and 14, the substrate 100 may include dummy fins DF, which are defined by the device isolation layer 101 and extend in the first direction X. The dummy fins DF may be arranged in the second direction Y. Dummy transistors DTR may be disposed on the second region 11 of the substrate 100. The dummy transistors DTR may extend in the second direction Y and run across the dummy fins DF, and may be disposed on the top surface of the device isolation layer 101 on the second region 11 of the substrate 100. The dummy transistors DTR may be spaced apart from each other in the first direction X. Although not shown, the dummy fins DF crossing the dummy transistors DTR may have first segments whose top surfaces vertically protrude from the top surface of the device isolation layer 101. Each of the dummy transistors DTR may include a dummy gate metal pattern 32a that surrounds top and lateral surfaces of the first segments of the dummy fins DF. Dummy semiconductor patterns DSP may be disposed on second segments between the first segments of the dummy fins DF. The second segments of the dummy fins DF may have their top surfaces at lower levels than those of the top surfaces of the first segments of the dummy fins DF. Each of the dummy transistors DTR may be interposed between the dummy semiconductor patterns DSP that are adjacent to each other in the first direction X. The dummy semiconductor patterns DSP may be adjacent to and spaced apart from each other in the second direction Y. Differently from that shown, the dummy semiconductor patterns DSP adjacent to each other in the second direction Y may be in physical contact with each other to form a single dummy semiconductor pattern.

The first interlayer dielectric layer 110 may cover the top surface of the device isolation layer 101, lateral surfaces of the dummy transistors DTR, and the dummy semiconductor patterns DSP. The second interlayer dielectric layer 112 may be disposed on the first interlayer dielectric layer 110. The second interlayer dielectric layer 112 may cover a top surface of the first interlayer dielectric layer 110 and a top surface of the dummy gate capping pattern 32b. First dummy contacts 610 may be disposed on the dummy transistors DTR. The first dummy contacts 610 may penetrate the second interlayer dielectric layer 112, the first interlayer dielectric layer 110, and the dummy gate capping pattern 32b, and may contact the dummy gate metal pattern 32a. The first dummy contacts 610 may extend in the second direction Y and may be arranged in the first direction X. The first dummy contacts 610 may include a metallic material, such as tungsten. Second dummy contacts 612 may extend in the second direction Y and may be spaced apart from each other in the first direction X. Each of the second dummy contacts 612 may be disposed on the dummy semiconductor patterns DSP adjacent to each other in the second direction Y. For example, each of the second dummy contacts 612 may penetrate the second interlayer dielectric layer 112 and the first interlayer dielectric layer 110, and may be in common contact with the dummy semiconductor patterns DSP adjacent to each other in the second direction Y. The second dummy contacts 612 adjacent to each other in the first direction X may be interposed between the first dummy contacts 610. The first and second dummy contacts 610 and 612 may have their top surfaces 44′ at the same level from the top surface of the substrate 100 as that of the top surface 40 of the second interlayer dielectric layer 112. In some example embodiments, the first dummy contact 610 and the second dummy contact 612 that are adjacent in the first direction X may constitute electrodes of a decoupling capacitor. The second dummy contacts 612 may include a metallic material, such as tungsten.

The third interlayer dielectric layer 126 may be disposed on the second interlayer dielectric layer 112. The third interlayer dielectric layer 126 may cover the top surface 40 of the second interlayer dielectric layer 112, the top surfaces 44′ of the first dummy contacts 610, and the top surfaces 44′ of the second dummy contacts 612. First dummy vias 622 may be disposed on the first dummy contacts 610. The first dummy vias 622 may penetrate the third interlayer dielectric layer 126, and may be in contact with and electrically connected to the first dummy contacts 610. In some example embodiments, when viewed in plan, the first dummy vias 622 may be disposed not to horizontally adjoin the second dummy contacts 612. For example, when viewed in plan, the first dummy vias 622 may not vertically overlap the second dummy contacts 612. The first dummy vias 622 adjacent in the first direction X on the first dummy contacts 610 that are different from each other may be aligned with each other in the first direction X. Second dummy vias 624 may be disposed on the second dummy contacts 612. The second dummy vias 624 may penetrate the third interlayer dielectric layer 126, and may be in contact with and electrically connected to the second dummy contacts 612. The second dummy vias 624 adjacent in the first direction X on the second dummy contacts 612 that are different from each other may be aligned with each other in the first direction X. The first and second dummy vias 622 and 624 may include a metallic material, such as tungsten.

First dummy conductive lines 632 may be disposed on the third interlayer dielectric layer 126. The first dummy conductive lines 632 may extend in the first direction X and may be spaced apart from each other in the second direction Y. The first dummy conductive lines 632 may be in contact with and electrically connected to the first dummy vias 622 that are aligned in the first direction X. Second dummy conductive lines 634 may be disposed on the third interlayer dielectric layer 126. The second dummy conductive lines 634 may extend in the first direction X and may be spaced apart from each other in the second direction Y. The second dummy conductive lines 634 may be in contact with and electrically connected to the second dummy vias 624 that are aligned in the first direction X. The first and second dummy conductive lines 632 and 634 may include a metallic material, such as tungsten.

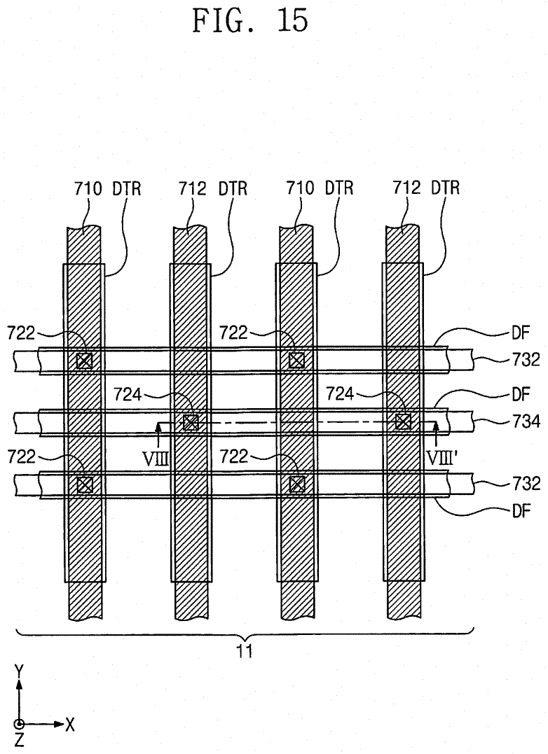

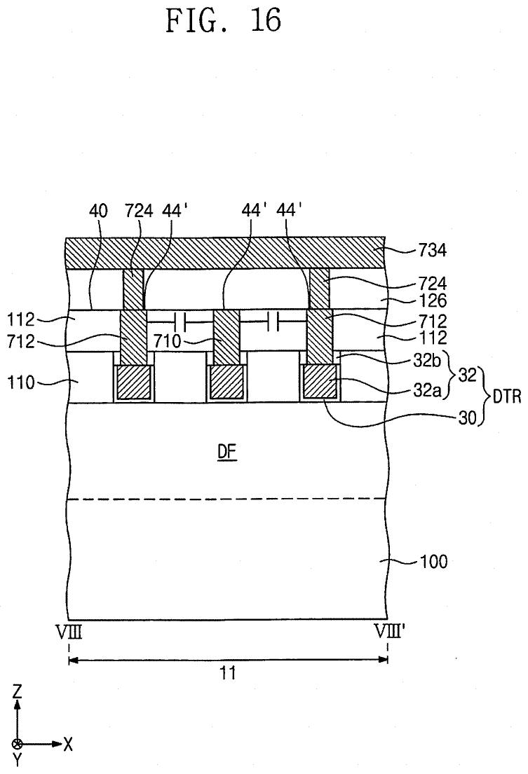

FIG. 15 illustrates a plan view showing a semiconductor device according to some example embodiments of the present inventive concepts. FIG. 16 illustrates a cross-sectional view taken along line VIII-VIII′ of FIG. 15, showing a semiconductor device according to some example embodiments of the present inventive concepts.

Referring to FIGS. 15 and 16, the dummy transistors DTR may extend in the second direction Y and may be spaced apart from each other in the first direction X. The dummy transistors DTR may run across the dummy fins DF that extend in the first direction X. The dummy transistors DTR may cover lateral and top surfaces of portions of the dummy fins DF that cross the dummy transistors DTR. First dummy contacts 710 and second dummy contacts 712 may be disposed on the dummy transistors DTR. The first and second dummy contacts 710 and 712 may penetrate the second interlayer dielectric layer 112 and the dummy gate capping patterns 32b, and may contact the dummy gate metal patterns 32a. The first and second dummy contacts 710 and 712 may extend in the second direction Y. The first and second dummy contacts 710 and 712 may be arranged alternately and repeatedly in the first direction X. The first and second dummy contacts 710 and 712 may be parallel to each other in the second direction Y. The first and second dummy contacts 710 and 712 may have their top surfaces 44′ at the same level from the top surface of the substrate 100 as that of the top surface 40 of the second interlayer dielectric layer 112. The first dummy contact 710 and the second dummy contact 712 that are adjacent in the first direction X may constitute electrodes of a decoupling capacitor. The first and second dummy contacts 710 and 712 may include a metallic material, such as tungsten.

First dummy vias 722 may be disposed on the first dummy contacts 710. The first dummy vias 722 may penetrate the third interlayer dielectric layer 126, and may be in contact with and electrically connected to the first dummy contacts 710. The first dummy vias 722 on the same first dummy contact 710 may be spaced apart from each other in the second direction Y. The first dummy vias 722 adjacent in the first direction X on the first dummy contacts 710 that are different from each other may be aligned with each other in the first direction X. Second dummy vias 724 may be disposed on the second dummy contacts 712. The second dummy vias 724 may penetrate the third interlayer dielectric layer 126, and may be in contact with and electrically connected to the second dummy contacts 712. The second dummy vias 724 on the same second dummy contact 712 may be spaced apart from each other in the second direction Y. The second dummy vias 724 adjacent in the first direction X on the second dummy contacts 712 that are different from each other may be aligned with each other in the first direction X. The first dummy vias 722 and their adjacent second dummy vias 724 may be arranged in a zigzag shape along the first and second directions X and Y. The first and second dummy vias 722 and 724 may include a metallic material, such as tungsten.

First dummy conductive lines 732 may be disposed on the first dummy vias 722. The first dummy conductive lines 732 may extend in the first direction X, and may be in contact with and electrically connected to the first dummy vias 722 aligned in the first direction X. Second dummy conductive lines 734 may be disposed on the second dummy vias 724. The second dummy conductive lines 734 may extend in the first direction X, and may be in contact with and electrically connected to the second dummy vias 724 aligned in the first direction X. The first dummy conductive lines 732 and the second dummy conductive lines 734 may be disposed alternately and repeatedly in the second direction Y. The first and second dummy conductive lines 732 and 734 may include a metallic material, such as tungsten.

According to some example embodiments of the present inventive concepts, dummy patterns and dummy vias may be formed for uniformity of a surface that will be polished when a chemical mechanical polishing (CMP) process is performed, and a pair of dummy patterns and a pair of dummy vias may be used as electrodes of decoupling capacitors. Therefore, because the dummy contacts and the dummy vias may be utilized as electrode of decoupling capacitors, a semiconductor device may improve in electrical characteristics.

Although the present inventive concepts have been described in connection with some example embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitutions, modifications, and changes may be thereto without departing from the scope and spirit of the inventive concepts.

What is claimed is:

1. A semiconductor device, comprising:
a substrate that includes a first region and a second region;
a switching transistor on the first region of the substrate;
an interlayer dielectric layer that covers the switching transistor and is on the second region of the substrate;
a cell contact that penetrates the interlayer dielectric layer on the first region of the substrate and is in contact with the switching transistor; and
a first dummy contact, a second dummy contact, and a third dummy contact that penetrate the interlayer dielectric layer on the second region of the substrate in a vertical direction that is perpendicular to a top surface of the substrate, the first dummy contact, the second dummy contact, and the third dummy contact being adjacent to each other in a first horizontal direction that is parallel to the top surface of the substrate,
wherein the first dummy contact and the second dummy contact constitute opposing electrodes of a first decoupling capacitor,
wherein the second dummy contact and the third dummy contact constitute opposing electrodes of a second decoupling capacitor, and
wherein the first, second, and third dummy contacts are electrically isolated from the substrate.

2. The semiconductor device of claim 1, further comprising:
a device isolation layer in the substrate,
wherein the first dummy contact, the second dummy contact, and the third dummy contact are in contact with a top surface of the device isolation layer.

3. The semiconductor device of claim 1, wherein
the first dummy contact, the second dummy contact, and the third dummy contact are in contact with the top surface of the substrate, and
the substrate does not include any impurity regions in the second region.

4. The semiconductor device of claim 1, wherein
the first dummy contact, the second dummy contact, and the third dummy contact each extend in a second horizontal direction that is parallel to the top surface of the substrate and intersects the first horizontal direction, and
the first dummy contact, the second dummy contact, and the third dummy contact each have a bar shape.

5. The semiconductor device of claim 1, further comprising:
a first dummy conductive line on the interlayer dielectric layer, the first dummy conductive line electrically connected, through separate, respective vias, to the first dummy contact and the third dummy contact; and
a second dummy conductive line on the interlayer dielectric layer, the second dummy conductive line electrically connected to the second dummy contact,
wherein the first dummy conductive line is electrically connected to a first voltage source that is configured to supply a first voltage, such that the first dummy conductive line is configured to receive the first voltage, the first voltage being one voltage of a power voltage or a ground voltage, and
wherein the second dummy conductive line is electrically connected to a second voltage source that is configured to supply a second voltage, such that the second dummy conductive line is configured to receive the second voltage, the second voltage being a separate voltage of the power voltage or the ground voltage.

6. The semiconductor device of claim 1, wherein a top surface of the cell contact is coplanar with a top surface of the interlayer dielectric layer and with top surfaces of each of the first, second, and third dummy contacts.

7. The semiconductor device of claim 1, further comprising:
a first dummy conductive line on the interlayer dielectric layer, the first dummy conductive line electrically connected, through separate, respective vias, to the first dummy contact and the third dummy contact; and
a second dummy conductive line on the interlayer dielectric layer, the second dummy conductive line electrically connected to the second dummy contact, the second dummy conductive line being adjacent to the first dummy conductive line in a second horizontal direction, the second horizontal direction that is parallel to the top surface of the substrate and intersects the first horizontal direction,
wherein the first dummy contact, the second dummy contact, and the third dummy contact each extend in the second horizontal direction and in parallel with each other, and
wherein the first dummy conductive line and the second dummy conductive line each extend in the first horizontal direction and in parallel with each other.

8. The semiconductor device of claim 7, further comprising:
a plurality of first dummy vias, one first dummy via being directly between the first dummy conductive line and the first dummy contact, another first dummy via being directly between the first dummy conductive line and the third dummy contact; and
a second dummy via directly between the second dummy conductive line and the second dummy contact,
wherein, when viewed in plan, the one first dummy via face in the second horizontal direction toward the other first dummy via, and
wherein the plurality of first dummy vias and the second dummy via are arranged in a zigzag shape along the first and second horizontal directions.

9. The semiconductor device of claim 8, wherein
the one first dummy via and the second dummy via constitute opposing electrodes of a third decoupling capacitor,
the semiconductor device includes a third dummy conductive line on the interlayer dielectric layer, the third dummy conductive line electrically connected to the third dummy contact, the third dummy conductive line being adjacent to the second dummy conductive line in the second horizontal direction, and
the semiconductor device includes a third dummy via directly between the third dummy conductive line and the third dummy contact, wherein the second dummy via and the third dummy via constitute opposing electrodes of a fourth decoupling capacitor.

10. The semiconductor device of claim 1, wherein
the switching transistor comprises:
a gate electrode on the first region of the substrate; and
a plurality of source/drain regions on the first region of the substrate at opposite sides of the gate electrode,
wherein the cell contact is in contact with one of the gate electrode or one source/drain region of the plurality of source/drain regions.

11. A semiconductor device, comprising:
a substrate that includes a first region and a second region;
a first impurity region, a second impurity region, and a third impurity region that are adjacent to each other in a first direction on the second region of the substrate;
an interlayer dielectric layer on the first and second regions of the substrate;
a first dummy contact in the interlayer dielectric layer and in contact with the first impurity region;
a second dummy contact in the interlayer dielectric layer and in contact with the second impurity region;
a third dummy contact in the interlayer dielectric layer and in contact with the third impurity region;
a first dummy conductive line on the interlayer dielectric layer and electrically connected, through separate, respective vias, to the first dummy contact and the third dummy contact; and
a second dummy conductive line on the interlayer dielectric layer and electrically connected to the second dummy contact.

12. The semiconductor device of claim 11, wherein
the first dummy contact and the second dummy contact constitute opposing electrodes of a first decoupling capacitor, and
the second dummy contact and the third dummy contact constitute opposing electrodes of a second decoupling capacitor.

13. The semiconductor device of claim 11, wherein
the first dummy conductive line is electrically connected to a first voltage source that is configured to supply a first voltage, such that the first dummy conductive line is configured to receive the first voltage, the first voltage being one voltage of a power voltage or a ground voltage, and
the second dummy conductive line is electrically connected to a second voltage source that is configured to supply a second voltage, such that the second dummy conductive line is configured to receive the second voltage, the second voltage being a separate voltage of the power voltage or the ground voltage.

14. The semiconductor device of claim 11, further comprising:
a device isolation layer that is in the substrate and defines first and second dummy fins on the second region of the substrate, wherein the first and second dummy fins extend in parallel in the first direction and are adjacent to each other in a second direction intersecting the first direction;
a first dummy semiconductor pattern, a second dummy semiconductor pattern, and a third dummy semiconductor pattern that are on the first dummy fin and are spaced apart from each other in the first direction; and
a fourth dummy semiconductor pattern, a fifth dummy semiconductor pattern, and a sixth dummy semiconductor pattern that are on the second dummy fin and are spaced apart from each other in the first direction,
wherein the first impurity region is in each of the first dummy semiconductor pattern and the fourth dummy semiconductor pattern,
wherein the second impurity region is in each of the second dummy semiconductor pattern and the fifth dummy semiconductor pattern; and
wherein the third impurity region is in each of the third dummy semiconductor pattern and the sixth dummy semiconductor pattern.

15. The semiconductor device of claim 14, wherein
the first dummy contact is in contact with the first dummy semiconductor pattern and the fourth dummy semiconductor pattern,
the second dummy contact is in contact with the second dummy semiconductor pattern and the fifth dummy semiconductor pattern, and
the third dummy contact is in contact with the third dummy semiconductor pattern and the sixth dummy semiconductor pattern, and
the first dummy contact, the second dummy contact, and the third dummy contact have a bar shape extending in the second direction.

16. The semiconductor device of claim 11, further comprising:
a switching transistor on the first region of the substrate, the switching transistor including a gate electrode on the substrate and a plurality of source/drain regions at opposite sides of the gate electrode;
a plurality of first cell contacts that penetrate the interlayer dielectric layer and are in contact with separate, respective source/drain regions of the plurality of source/drain regions; and
a second cell contact that penetrates the interlayer dielectric layer and is in contact with the gate electrode,
wherein top surfaces of the first, second, and third dummy contacts and top surfaces of the first and second cell contacts are coplanar with each other.

17. A semiconductor device, comprising:
a substrate that includes a first region and a second region;
a switching transistor on the first region of the substrate, the switching transistor including a gate electrode on the substrate and a source/drain region on the first region, the source/drain region on one side of the gate electrode;
an interlayer dielectric layer that covers the switching transistor and is on the second region of the substrate;
a first dummy contact and a second dummy contact that penetrate the interlayer dielectric layer on the second region of the substrate in a vertical direction that is perpendicular to a top surface of the substrate, the first dummy contact and the second dummy contact being adjacent to each other in a first horizontal direction that is parallel to the top surface of the substrate; and
a cell contact that penetrates the interlayer dielectric layer and is in contact with the source/drain region,
wherein a top surface of the first dummy contact, a top surface of the second dummy contact, and a top surface of the cell contact are coplanar with each other, and
wherein the first dummy contact and the second dummy contact constitute opposing electrodes of a decoupling capacitor.

18. The semiconductor device of claim 17, wherein the first and second dummy contacts are electrically and/or physically isolated from the substrate.

19. The semiconductor device of claim 17, wherein the first dummy contact and the second dummy contact penetrate the interlayer dielectric layer.

20. The semiconductor device of claim 17, further comprising:
a dummy transistor between the second dummy contact and the second region of the substrate,
wherein the dummy transistor includes a dummy gate dielectric layer on the second region of the substrate, a dummy gate metal pattern on the dummy gate dielectric layer, and a dummy gate capping pattern on the dummy gate metal pattern.
